(19) United States
(12) Patent Application Publication
(10) Pub. No.: US 2025/0234486 A1
(43) Pub. Date: Jul. 17, 2025

(54) HEAT DISSIPATION LIQUID COOLING SINK

(71) Applicants: Jian-Chang Precision Ltd., New Taipei City (TW); Guangzhou Yijia Electronic Co. , Ltd., Guangzhou (CN)

(72) Inventors: Kai-Lin SYU, Taipei City (TW); Jia-Xiu ZHOU, Guangzhou (CN)

(21) Appl. No.: 19/013,387

(22) Filed: Jan. 8, 2025

(30) Foreign Application Priority Data
Jan. 11, 2024 (CN) 202420072589.5

(51) Int. Cl. H05K 7/20

(52) U.S. Cl. CPC H05K 7/20272

(57) ABSTRACT

A heat dissipation liquid cooling sink includes a base, a cap shell, a liquid chamber defined by the base and the cap shell, and a flow guide structure. The base includes at least one cooling fin set. The cap shell includes a liquid inlet and a liquid outlet. The flow guide structure is located in the liquid chamber and stacked over the fin set, and defines a liquid inlet passage and a liquid outlet passage. The liquid inlet passage includes a liquid intake position at the liquid chamber and a liquid exit position at the cooling fin set. The heat dissipation liquid cooling sink includes a first path from the liquid chamber directly to the cooling fin set and a second path from the liquid inlet passage to the cooling fin set. The first path and the second path flow into the cooling fin set at different positions.

### CROSS-REFERENCE TO RELATED APPLICATION

The present application claims priority to China Patent App. No. 202420072589.5, filed Jan. 11, 2024, the entirety of which are incorporated by reference herein

### FIELD OF THE INVENTION

The invention relates to a heat dissipation liquid cooling sink, and more particularly to a liquid cooling sink with a flow guiding structure.

### BACKGROUND OF THE INVENTION

The liquid flow designs of existing heat dissipation liquid cooling sinks are disclosed in TW 1800185B, EP 3577406B, US 10932391B, US 2004052663A, US 2012175094A, US 2022232733A, TW I794811B, and CN 204836927U.

The heat dissipation liquid cooling sinks disclosed in the aforementioned patents are provided with a single liquid flow path. In general, a liquid outlet of existing heat dissipation liquid cooling sink is positioned at the center of a cooling fin set. That is, cooling liquid flows from a liquid inlet through a periphery of the cooling fin set to the center, and then exits from the liquid outlet. Such design of a liquid path easily leads to a portion of the cooling fin set located at the periphery thereof achieving a good heat exchange effect, while a portion of the cooling fin set located in the center does not achieve the same effect by being limited by a thermal energy in the cooling liquid.

### SUMMARY OF THE INVENTION

A main object of the invention is to solve the problem that the conventional heat dissipation liquid cooling sinks cannot provide a good heat dissipation effect of a cooling fin set.

In order to achieve the above object, the invention provides a heat dissipation liquid cooling sink, including a base, a cap shell, and a liquid chamber defined by the base and the cap shell. The base includes at least one cooling fin set, and the cap shell is formed with a liquid inlet and a liquid outlet. The heat dissipation liquid cooling sink includes a flow guide structure located in the liquid chamber and stacked over the at least one set of heat dissipation fins. The flow guide structure defines at least one liquid inlet passage and a liquid outlet passage. The at least one liquid inlet passage includes a liquid intake position introducing liquid from the liquid chamber and a liquid exit position for discharging liquid from the at least one set of heat dissipation fins. The liquid outlet passage communicates with the liquid outlet. The heat dissipation liquid cooling sink forms a first path where liquid flows directly from the liquid chamber to the at least one cooling fin set, and a second path where liquid flows from the liquid outlet passage to the at least one cooling fin set. A position where the first path flows into the at least one cooling fin set is different from a position where the second path flows into the at least one cooling fin set.

In one embodiment, the flow guiding structure is formed on a side of the cap shell facing the base.

In one embodiment, the heat dissipation liquid cooling sink includes a flow guiding base provided in the liquid chamber and connected to the cap shell, and the flow guiding structure is formed jointly by the flow guiding base and the cap shell.

In one embodiment, the flow guiding base is formed with at least one first opening for constituting the at least one liquid inlet passage, and a second opening for constituting the liquid outlet passage.

In one embodiment, the cap shell is formed with an assembly notch located at the liquid intake position of the at least one liquid inlet passage, and the flow guiding base includes an assembly block positioned at the assembly notch.

In one embodiment, the cap shell is provided with a groove on a side facing the flow guiding base, and the flow guiding base is provided with a liquid-blocking ring located in the groove and at least one rib connecting to the liquid-blocking ring.

In one embodiment, the heat dissipation liquid cooling sink further includes an auxiliary guide plate located in the liquid chamber and connected to the flow guiding base, and the flow guiding structure is formed jointly by the cap shell, the flow guiding base, and the auxiliary guide plate.

In one embodiment, the auxiliary guide plate includes at least one first through hole for constituting the at least one liquid inlet passage corresponded to the at least one first opening, and a second through hole for constituting the liquid outlet passage corresponded to the second opening.

In one embodiment, the at least one cooling fin set is provided in multiple sets, and a plurality of cooling fin sets are located on two opposite surfaces of the flow guiding base.

In one embodiment, the heat dissipation liquid cooling sink includes a driving device located inside the cap shell, and an impeller connected to the driving device, the impeller includes a hollow casing, a plurality of axial blades arranged inside the hollow casing, and a plurality of centrifugal blades arranged inside the hollow casing closer to the liquid outlet than the plurality of axial blades.

Through the foregoing implementation of the invention, compared with the prior art, the invention has the following characteristic: by arranging the flow guiding structure, the first path and the second path are formed within the heat dissipation liquid cooling sink of the invention, enabling the at least one cooling fin set to achieve a good heat exchange effect.

### BRIEF DESCRIPTION OF THE DRAWINGS

FIG. 1 is a first exploded schematic diagram of an embodiment of the invention.

FIG. 2 is a second exploded schematic diagram of an embodiment of the invention.

FIG. 3 is a schematic top view of a housing according to an embodiment of the invention.

FIG. 4 is a schematic cross-sectional view of line segment A-A of FIG. 3.

FIG. 5 is a schematic cross-sectional view of line segment B-B in FIG. 3.

FIG. 6 is a schematic diagram of an embodiment of the invention.

### DETAILED DESCRIPTION OF THE PREFERRED EMBODIMENTS

The detailed description and technical content of the invention are described below with reference to the accompanying drawings.

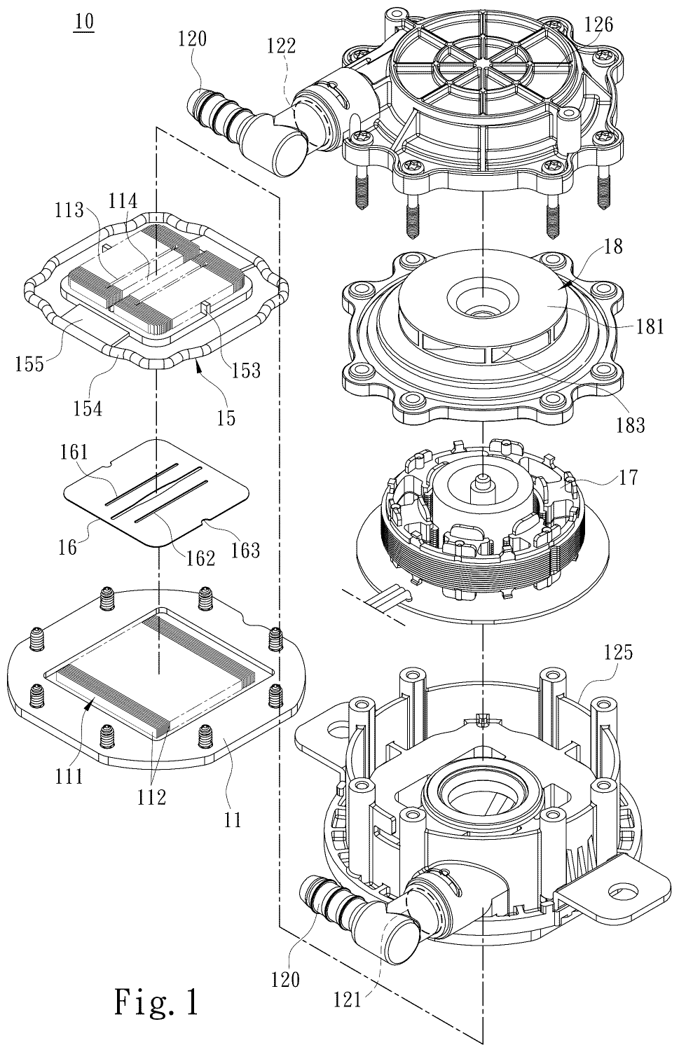

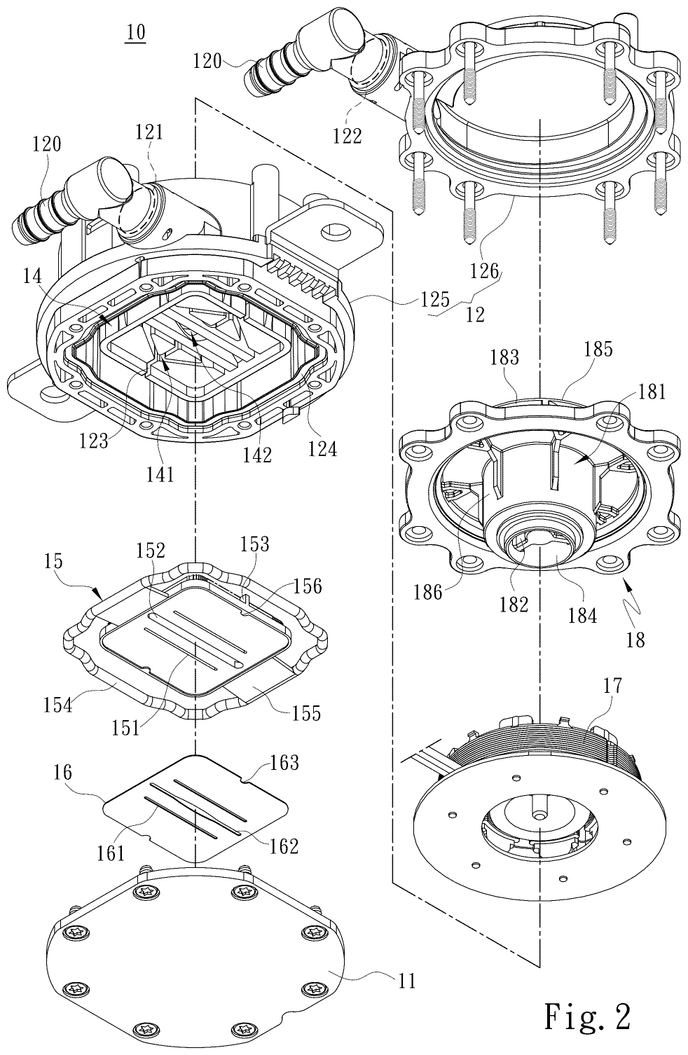

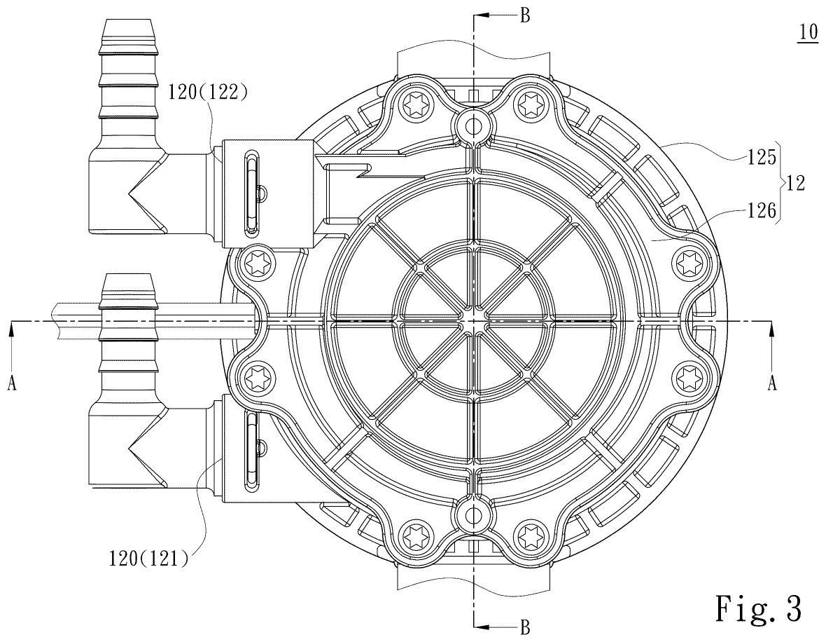

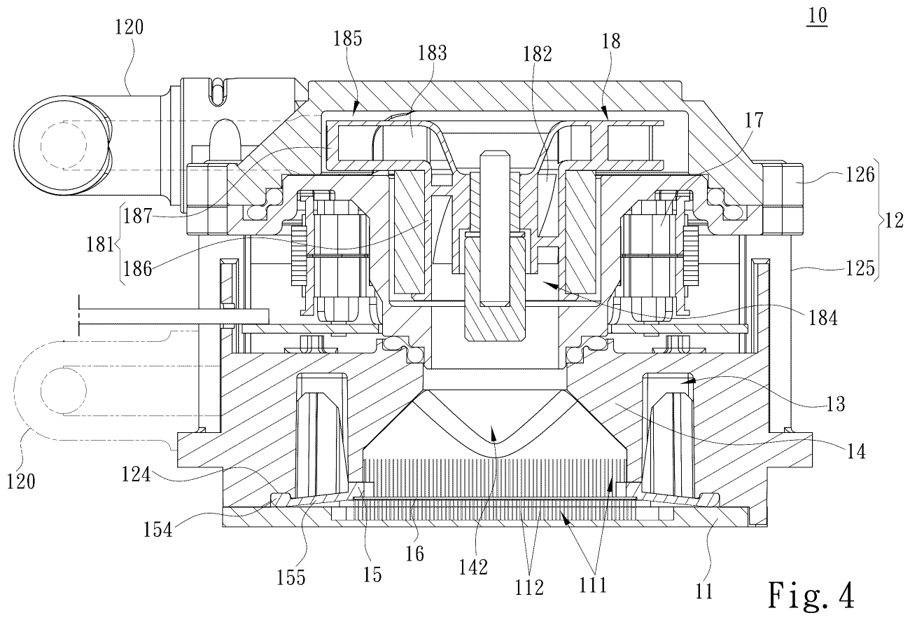

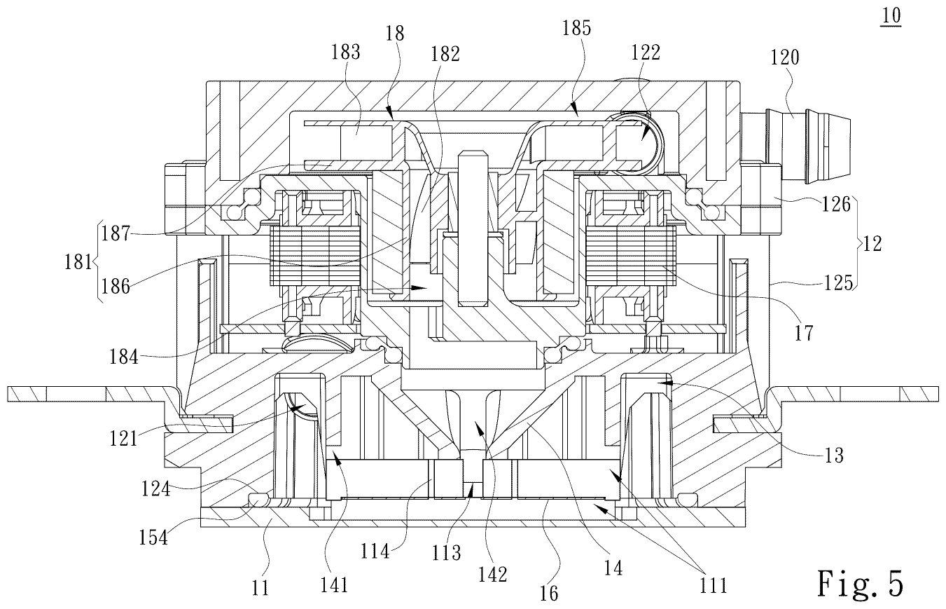

Please refer to FIG. 1, FIG. 2, FIG. 3, FIG. 4 and FIG. 5. The invention provides a heat dissipation liquid cooling sink 10, which can come into contact with a heat-generating component (not shown in the figure) to dissipate waste heat generated when the component operates, thereby allowing the component to be cooled. The heat-generating component may be a central processing unit (CPU), a graphics processing unit (GPU), a memory, or a solid-state drive (SSD), etc. The heat dissipation liquid cooling sink 10 includes a base 11, a cap shell 12 connected to the base 11, and a liquid chamber 13 defined by both the base 11 and the cap shell 12. The base 11 contacts the heat-generating component and is provided with at least one cooling fin set 111, which allows the at least one cooling fin set 111 receives a thermal energy from the heat-generating component. The cap shell 12 is provided with a liquid inlet 121 and a liquid outlet 122, and the liquid inlet 121 and the liquid outlet 122 respectively communicate with the liquid chamber 13.

Please refer to FIG. 1, FIG. 2, FIG. 3, FIG. 4, and FIG. 5 again. The heat dissipation liquid cooling sink 10 includes a flow guiding structure 14 located within the liquid chamber 13 and stacked on the in at least one cooling fin set 111. The flow guiding structure 14 defines at least one liquid inlet passage 141 and a liquid outlet passage 142. The at least one liquid inlet passage 141 is communicated to the liquid inlet 121, while the liquid outlet passage 142 is communicated to the liquid outlet 122. The two ends of the at least one liquid inlet passage 141 are a liquid intake position and a liquid exit position, where the liquid intake position introduces liquid from the liquid chamber 13, and the liquid exit position discharges liquid to a top portion of the at least one cooling fin set 111. In other words, the at least one liquid inlet passage 141 introduces liquid to the at least one cooling fin set 111, and the liquid outlet passage 142 introduces liquid from the at least one cooling fin set 111. Furthermore, the heat dissipation liquid cooling sink 10 forms a first path 101 where liquid directly flows from the liquid chamber 13 to the at least one cooling fin set 111, and a second path 102 where liquid flows from the at least one liquid inlet passage 141 to the at least one cooling fin set 111.

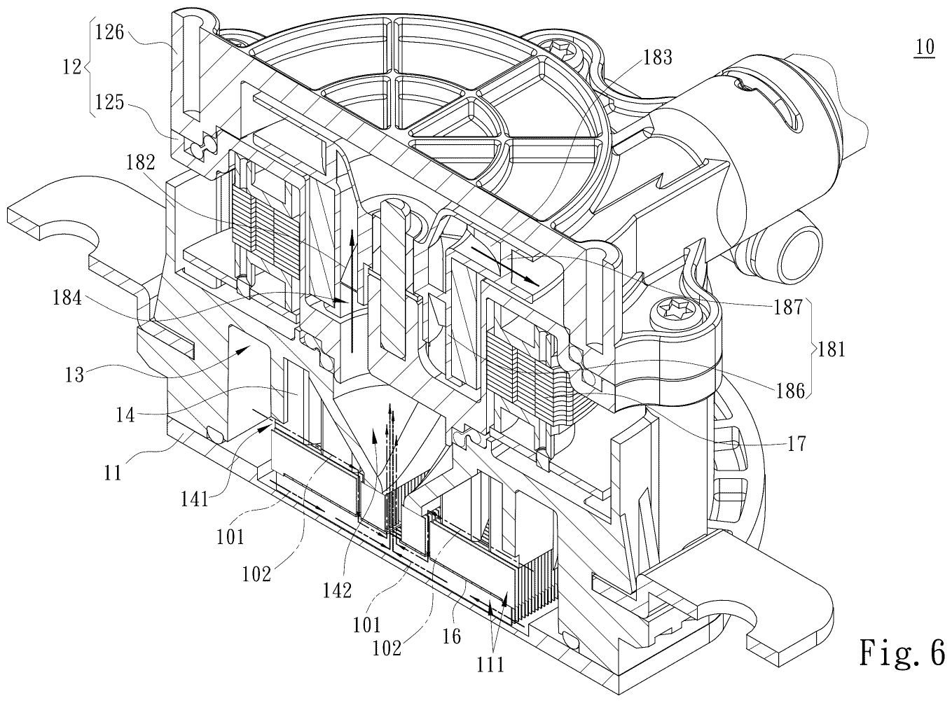

An implementation of the heat dissipation liquid cooling sink 10 will now be described. Please refer to FIG. 3, FIG. 4, FIG. 5, and FIG. 6. The liquid inlet 121 and the liquid outlet 122 of the heat dissipation liquid cooling sink 10 are respectively connected to a connector 120 to connect to a cooling radiator (not shown in the figure), such that the heat dissipation liquid cooling sink 10 and the cooling radiator form a circulating heat dissipation system. Inside this circulating heat dissipation system, there is a cooling liquid 50 used for heat exchange with the at least one cooling fin set 111. The heat dissipation liquid cooling sink 10 receives the cooling liquid 50 through the liquid inlet 121, and after entering the liquid chamber 13 through the liquid inlet 121, a portion of the cooling liquid 50 flows along the first path 101, and the remaining portion of the cooling liquid 50 flows along the second path 102. Specifically, the portion of the cooling liquid 50 flowing along the first path 101 flows directly from the liquid chamber 13 to the at least one cooling fin set 111, and flows from a periphery towards the center of the at least one cooling fin set 111 for heat exchange. Subsequently, the portion of the cooling liquid 50 flows to the liquid outlet 122 via the liquid outlet passage 142. The remaining portion of the cooling liquid 50 flowing along the second path 102 flows from the liquid intake position of the at least one liquid inlet passage 141 to the liquid exit position of the at least one liquid inlet passage 141, discharging to the top portion of the at least one cooling fin set 111 and performing heat exchange with the at least one cooling fin set 111. Subsequently, the cooling liquid 50 converges into the liquid outlet passage 142 and is discharged through the liquid outlet 122.

Accordingly, the cooling liquid 50 of the invention enters the liquid chamber 13 through the liquid inlet 121, and then flows along the first path 101 and the second path 102 towards the at least one cooling fin set 111. Since the first path 101 flows into the at least one cooling fin set 111 at a different position than the second path 102 flows into the at least one cooling fin set 111, the entire at least one cooling fin set 111 can achieve a good heat exchange effect. After completing the heat exchange, the cooling liquid 50 converges into the liquid outlet passage 142, and flows along the liquid outlet passage 142 towards the liquid outlet 122, and finally undergoes heat exchange again with the cooling radiator, before flowing back to the heat dissipation liquid cooling sink 10 for further cooling.

Compared to conventional designs, through the arrangement of the flow guiding structure 14 of the invention, allowing the cooling liquid 50 to separately flow along the first path 101 and the second path 102 to perform heat exchange with the at least one cooling fin set 111. This ensures that the entire at least one cooling fin set 111 receives efficient heat dissipation, and reduces the problem in conventional cooling fin sets where only partial areas can achieve heat dissipation, while the remaining areas of the cooling fin set are unable to achieve effective heat exchange due to a high heat content in the cooling liquid.

Please refer to FIG. 1, FIG. 2, FIG. 3, FIG. 4, and FIG. 5. In one embodiment, the flow guiding structure 14 of the invention can be integrally formed by the cap shell 12, and one side of the cap shell 12 facing the base 11 forms the at least one liquid inlet passage 141 and the liquid outlet passage 142. In another embodiment, the heat dissipation liquid cooling sink 10 of the invention further includes a flow guiding base 15 provided in the liquid chamber 13, the flow guiding base 15 is connected to the cap shell 12 and stacked above the at least one cooling fin set 111, and the flow guiding structure 14 is formed jointly by the flow guiding base 15 and the cap shell 12.

The flow guiding base 15 is formed with at least one first opening 151 for constituting the at least one liquid inlet passage 141 and a second opening 152 for constituting the liquid outlet passage 142. The at least one first opening 151 and the second opening 152 are not in communication with each other. Furthermore, in order to enhance the heat dissipation performance of the at least one cooling fin set 111, the at least one cooling fin set 111 is composed of multiple fins 112 arranged at intervals. An extending direction of the at least one first opening 151 is the same as an extending direction of the second opening 152, which is different from an extending direction of gaps between the fins 112.

Furthermore, please refer to FIG. 2, FIG. 4, FIG. 5, and FIG. 6. For assembling the flow guiding base 15 and the cap shell 12, in one embodiment, the cap shell 12 is formed with an assembly notch 123 located at the liquid intake position of the at least one liquid inlet passage 141. The flow guiding base 15 includes an assembly block 153 that is positioned at the assembly notch 123. After the assembly block 153 is connected with the assembly notch 123, the assembly notch 123 is not fully closed, the assembly block 153 and the assembly notch 123 jointly form the at least one liquid inlet passage 141.

Moreover, to improve the liquid resistance effect after the assembly of the flow guiding base 15 and the cap shell 12, the cap shell 12 is provided with a groove 124 on a side facing the flow guiding base 15. An opening direction of the groove 124 faces the flow guiding base 15, and the flow guiding base 15 is provided with a liquid-blocking ring 154 located in the groove 124, as well as at least one rib 155 connecting to the liquid-blocking ring 154.

In another embodiment, please refer to FIG. 2, FIG. 4, and FIG. 6. The heat dissipation liquid cooling sink 10 further includes an auxiliary guide plate 16 located in the liquid chamber 13 and connected to the flow guiding base 15. The flow guiding structure 14 can thus be formed jointly by the cap shell 12, the flow guiding base 15, and the auxiliary guide plate 16. More specifically, the auxiliary guide plate 16 is positioned on a side of the flow guiding base 15 that faces the base 11, and a structure of the auxiliary guide plate 16 is designed to fit with the flow guiding base 15. The auxiliary guide plate 16 includes at least one first through hole 161 for constituting the at least one liquid inlet passage 141 and a second through hole 162 for constituting the liquid outlet passage 142. A position of the at least one first through hole 161 corresponds to and communicates with the at least one first opening 151 of the flow guiding base 15, while a position of the second through hole 162 corresponds to and communicates with the second opening 152 of the flow guiding base 15. Additionally, to stabilize the assembly of the auxiliary guide plate 16 and the flow guiding base 15, the flow guiding base 15 is provided with at least one protrusion 156, and the auxiliary guide plate 16 includes at least one groove 163 that engages with the at least one protrusion 156.

Furthermore, please refer to FIG. 1 to FIG. 2 and FIG. 5. In one embodiment, the at least one cooling fin set 111 of the invention may be provided in multiple sets. The plurality of cooling fin sets 111 are located on two opposite surfaces of the flow guiding base 15, with at least one of the plurality of cooling fin sets 111 positioned on a side of the base 11 facing the flow guiding base 15, and at least the other one of the plurality of cooling fin sets 111 positioned on a side of the flow guiding base 15 facing the cap shell 12. Moreover, the plurality of cooling fin sets 111 arranged on the flow guiding base 15 form at least one first through hole 113 that connects to the at least one first opening 151, and a second through hole 114 that connects to the second opening 152. The at least one first through hole 113 and the second through hole 114 are not in communication with each other. The second through hole 114 may be formed by one of the plurality of cooling fin sets 111, or the second through hole 114 may be formed by a spacing between two of the plurality of cooling fin sets 111.

Further, please refer to FIG. 4, FIG. 5, and FIG. 6. In one embodiment, the heat dissipation liquid cooling sink 10 of the invention includes a driving device 17 located inside the cap shell 12 and an impeller 18 connected to the driving device 17. When the driving device 17 is activated, the impeller 18 is driven, thereby causing the cooling liquid 50 inside the heat dissipation liquid cooling sink 10 to flow. Furthermore, the impeller 18 includes a hollow casing 181, a plurality of axial blades 182 arranged inside the hollow casing 181, and a plurality of centrifugal blades 183 arranged inside the hollow casing 181. More specifically, the hollow casing 181 communicates the liquid outlet passage 142 and the liquid outlet 122, and defines a liquid inlet side 184 near the liquid outlet passage 142 and a liquid outlet side 185 near the liquid outlet 122. The plurality of axial blades 182 are arranged on the liquid inlet side 184 of the hollow casing 181, while the plurality of centrifugal blades 183 are arranged on the liquid outlet side 185 of the hollow casing 181, which is closer to the liquid outlet than the plurality of axial blades. When the impeller 18 rotates, the plurality of axial blades 182 provide a driving force to the cooling liquid 50 to flow toward the plurality of centrifugal blades 183, accelerating the extraction of the cooling liquid 50. The plurality of centrifugal blades 183 provide a centrifugal force to the cooling liquid 50, accelerating and throwing the cooling liquid 50 out of the impeller 18. In one embodiment, the hollow casing 181 includes a casing base 186 with the plurality of axial blades 182, and a cap 187 connected to the casing base 186. A diameter of the casing base 186 is smaller than a diameter of the cap 187.

Additionally, the cap shell 12 may further include a housing 125 that houses the driving device 17 and the impeller 18, and an upper cover 126 connected to the housing 125 and covering the impeller 18. The upper cover 126 can be detached from the housing 125 to facilitate maintenance of the driving device 17 and the impeller 18. In this embodiment, the housing 125 forms the liquid inlet 121, and the upper cover 126 forms the liquid outlet 122.

What is claimed is:

1. A heat dissipation liquid cooling sink, comprising a base, a cap shell connected to the base, and a liquid chamber defined by both the base and the cap shell, the base comprising at least one cooling fin set, the cap shell provided with a liquid inlet and a liquid outlet, and the heat dissipation liquid cooling sink is characterized in that:
the heat dissipation liquid cooling sink comprises a flow guiding structure located within the liquid chamber and stacked on the at least one cooling fin set, the flow guiding structure is defined with at least one liquid inlet passage and a liquid outlet passage, the at least one liquid inlet passage comprises a liquid intake position for introducing liquid from the liquid chamber and a liquid exit position for discharging liquid to a top portion of the at least one cooling fin set, the liquid outlet passage is communicated with the liquid outlet, the heat dissipation liquid cooling sink is provided with a first path where liquid directly flowing from the liquid chamber to the at least one cooling fin set and a second path where liquid flowing from the at least one liquid inlet passage to the at least one cooling fin set, and a position where the first path flowing into the at least one cooling fin set is different from a position where the second path flowing into the at least one cooling fin set.

2. The heat dissipation liquid cooling sink as claimed in claim 1, wherein the flow guiding structure is formed on a side of the cap shell facing the base.

3. The heat dissipation liquid cooling sink as claimed in claim 2, wherein the heat dissipation liquid cooling sink comprises a flow guiding base provided in the liquid chamber and connected to the cap shell, and the flow guiding structure is formed jointly by the flow guiding base and the cap shell.

4. The heat dissipation liquid cooling sink as claimed in claim 3, wherein the flow guiding base is formed with at least one first opening for constituting the at least one liquid inlet passage, and a second opening for constituting the liquid outlet passage.

5. The heat dissipation liquid cooling sink in claim 4, wherein the cap shell is formed with an assembly notch located at the liquid intake position of the at least one liquid inlet passage, and the flow guiding base comprises an assembly block positioned at the assembly notch.

6. The heat dissipation liquid cooling sink as claimed in claim 5, wherein the cap shell is provided with a groove on a side facing the flow guiding base, and the flow guiding base is provided with a liquid-blocking ring located in the groove and at least one rib connecting to the liquid-blocking ring.

7. The heat dissipation liquid cooling sink as claimed in claim 4, wherein the heat dissipation liquid cooling sink further comprises an auxiliary guide plate located in the liquid chamber and connected to the flow guiding base, and the flow guiding structure is formed jointly by the cap shell, the flow guiding base, and the auxiliary guide plate.

8. The heat dissipation liquid cooling sink as claimed in claim 7, wherein the auxiliary guide plate comprises at least one first through hole for constituting the at least one liquid inlet passage corresponded to the at least one first opening, and a second through hole for constituting the liquid outlet passage corresponded to the second opening.

9. The heat dissipation liquid cooling sink as claimed in claim 3, wherein the at least one cooling fin set is provided in multiple sets, and the plurality of cooling fin sets are located on two opposite surfaces of the flow guiding base.

10. The heat dissipation liquid cooling sink as claimed in claim 1, wherein the heat dissipation liquid cooling sink comprises a driving device located inside the cap shell and an impeller connected to the driving device, the impeller comprises a hollow casing, a plurality of axial blades arranged inside the hollow casing, and a plurality of centrifugal blades arranged inside the hollow casing and closer to the liquid outlet than the plurality of axial blades.
